(19) United States
(12) Patent Application Publication
(10) Pub. No.: US 2014/0372050 A1
(43) Pub. Date: Dec. 18, 2014

(54) LIFE DIAGNOSIS METHOD FOR POWER STORAGE DEVICE

(71) Applicants: Yoshinori Kanda, Chiyoda-ku (JP); Tetsuya Okuda, Chiyoda-ku (JP)

(72) Inventors: Yoshinori Kanda, Chiyoda-ku (JP); Tetsuya Okuda, Chiyoda-ku (JP)

(73) Assignee: MITSUBISHI ELECTRIC CORPORATION, Chiyoda-ku, Tokyo (JP)

(21) Appl. No.: 14/375,885

(22) PCT Filed: Mar. 27, 2012
(86) PCT No.: PCT/JP2012/058018

§ 371 Date: Jul. 31, 2014

(51) Int. Cl. G01R 31/02

(52) U.S. Cl. CPC G01R 31/028
USPC 702/57

(57) ABSTRACT

During initial charging for forming a predetermined bus voltage in a direct-current bus performed in a converter circuit when power is supplied to a motor control apparatus to which a power storage apparatus is connected, a step-down switching element in a step-up/down chopper circuit in the power storage apparatus is caused to perform ON/OFF operations a predetermined times to apply the initial charging to a power storage device, actual capacitance of the power storage device is calculated from total energy given to the power storage device in a period of the ON/OFF operations performed the predetermined times and a charging voltage indicated by the power storage device, and the calculated actual capacitance and initial capacitance of the power storage device are compared to estimate a deterioration degree of the power storage device and diagnose the life of the power storage device.

### FIELD

The present invention relates to a life diagnosis method for a power storage device that carries out life diagnosis of a power storage device in a power storage apparatus connected to a direct-current bus of a motor control apparatus.

### BACKGROUND

For example, in a motor control apparatus that performs driving control of a motor in an industrial machine such as a numerical-control machine tool or a press machine, a power storage apparatus is connected to a direct-current bus. Direct-current power for temporarily supplementing (assisting) direct-current power output to the direct-current bus by a converter circuit during power running of the motor can be supplied from the power storage device to the direct-current bus. Regenerative power generated by the motor during regeneration of the motor is output from an inverter circuit to the direct-current bus. Therefore, a configuration for enabling the regenerative power to be stored in the power storage apparatus is adopted.

In a power storage device used in the power storage apparatus of this type, an electrolytic capacitor and an electric double layer capacitor are used. In this power storage device, capacitance and a characteristic of internal resistance are deteriorated according to repetition of charging and discharging. Therefore, it is determined that the power storage device has exhausted its life when a degree of the deterioration of the power storage device reaches a predetermined design value. It is necessary to estimate the life of the power storage device to enable treatment such as replacing the power storage device before a system to which the motor control apparatus is supplied suddenly abnormally stops because of the deterioration and the exhaustion of the life of the storage device. As the conventional technologies for estimating the life of a power storage device, for example, methods proposed in Patent Literatures 1 and 2 are known.

Patent Literature 1 proposes a diagnosis method in which a voltage and a temperature during the operation of the apparatus are measured, an estimated deterioration degree of a capacitor is calculated from the measurement data using a deterioration coefficient corresponding to the voltage and temperature derived from the measurement data of a discharge amount in a deterioration test, the capacitor is charged and discharged with a fixed current, voltages immediately before and immediately after the charging and discharging and during the charging are measured, an actual deterioration degree of the capacitor is calculated with an actual-deterioration-degree calculating unit, and, when the difference between the estimated deterioration degree and the actual deterioration degree exceeds a reference value, it is determined that an abnormality of the capacitor has occurred.

Patent Literature 2 proposes a diagnosis method in which a pulse charging or a pulse discharging to a test target battery or power storage device is applied, to thereby measure a battery voltage waveform during the charging or the discharging, and a voltage change gradient (ΔV/Δt) of a change in the battery voltage per unit time is measured, and the life of the battery is thereby determined.

### CITATION LIST

### Patent Literature

Patent Literature 1: Japanese Patent No. 404291

Patent Literature 2: Japanese Patent Application Laid-Open No. 2007-187533

### SUMMARY

### Technical Problem

However, in both the conventional technologies described in Patent Literature 1 and Patent Literature 2, special circuits such as a circuit for detecting temperature and a circuit for life diagnosis and a separate apparatus such as a life diagnosis apparatus are necessary to diagnose the life. Further, an operation in a special life estimation mode is necessary other than a normal working operation mode. An increase in costs is caused when these methods are adopted and setting of a circuit for fixing an electric current and setting a separate apparatus and a special mode for performing life diagnosis are performed.

The present invention has been devised in view of the above and it is an object of the present invention to obtain a life diagnosis method for a power storage device that can carry out life diagnosis of the power storage device in a power storage apparatus connected to a direct-current bus of a motor control apparatus using an existing circuit in the power storage device without requiring a special circuit and a special mode.

### Solution to Problem

In order to solve the aforementioned problems, a life diagnosis method for a power storage device according to one aspect of the present invention, wherein the power storage device is included in a power storage apparatus connected to a direct-current bus in parallel to an inverter circuit in a motor control apparatus including a converter circuit that converts an alternating-current power supply into a direct-current power supply, and the inverter circuit that converts direct-current power output to the direct-current bus by the converter circuit and generates alternating-current power for controlling to drive a motor, the power storage apparatus including the power storage device, a step-up/down chopper circuit provided between the power storage device and the direct-current bus, and a control unit that performs discharging control for causing the step-up/down chopper circuit to perform a step-up operation and causing the power storage device to supply, to the direct-current bus, the direct-current power for supplementing the direct-current power output to the direct-current bus by the converter circuit and charging control for causing the step-up/down chopper circuit to perform a step-down operation and causing the power storage device to store regenerative power generated by the motor and output from the inverter circuit to the direct-current bus, wherein the life diagnosis for the power storage device carried out by the control unit during initial charging for forming a predetermined bus voltage in the direct-current bus performed in the converter circuit when power is supplied to the motor control apparatus comprises: a step of causing a step-down switching element to perform ON/OFF operations a predetermined times in the step-up/down chopper circuit to step down the predetermined bus voltage formed in the direct-current bus by the converter circuit, and applying the initial charging to the power storage device; a step of calculating total energy given to the power storage device in a period in which the ON/OFF operations are performed the predetermined times; a step of calculating actual capacitance of the power storage device from the calculated total energy and a charging voltage indicated by the power storage device; and a step of estimating a deterioration degree of the power storage device and diagnosing the life of the power storage device on the basis of a comparison of the calculated actual capacitance and initial capacitance of the power storage device.

### Advantageous Effects of Invention

According to the present invention, it is possible to carry out the life diagnosis of a power storage device in a power storage apparatus connected to the direct-current bus of a motor control apparatus in parallel to the inverter circuit using the existing circuits (the chopper circuit and the control unit) in the power storage apparatus. Because a step-down switching element of the chopper circuit is driven to be turned on and off by a PWM signal used during a normal operation, initial charging to the power storage device is performed by current control of a variable frequency. Therefore, unlike the conventional technologies, it is unnecessary to charge at a fixed current, and also unnecessary to add a special circuit, a special mode, special adjustment and an additional apparatus for diagnosing the life. Consequently, it is possible to add, without increasing costs, an additional function of life diagnosis of the power storage device to the power storage apparatus, which is used by connecting to the direct-current bus of the motor control apparatus. Further, it is possible to display a deterioration degree of the power storage device, which is a diagnosis result, to a user. Therefore, there is an effect that the user can perform prior replacement preparation and can minimize an apparatus stop period for the replacement work.

### BRIEF DESCRIPTION OF DRAWINGS

FIG. 1 is a block diagram for explaining the configuration of a power storage device that carries out a life diagnosis method for a power storage device according to an embodiment of the present invention and a connection relation between the power storage apparatus and a motor control apparatus.

FIG. 2 is a flowchart for explaining an operation sequence of the motor control apparatus shown in FIG. 1.

FIG. 3 is a time chart for explaining an operation example of power assist and charging performed by the power storage apparatus shown in FIG. 1.

FIG. 4 is a time chart for explaining an example of the life diagnosis method for the power storage device carried out by the power storage apparatus shown in FIG. 1.

### DESCRIPTION OF EMBODIMENTS

An embodiment of a life diagnosis method for a power storage device according to the present invention is explained in detail below with reference to the drawings. Note that the present invention is not limited by the embodiment.

### Embodiment

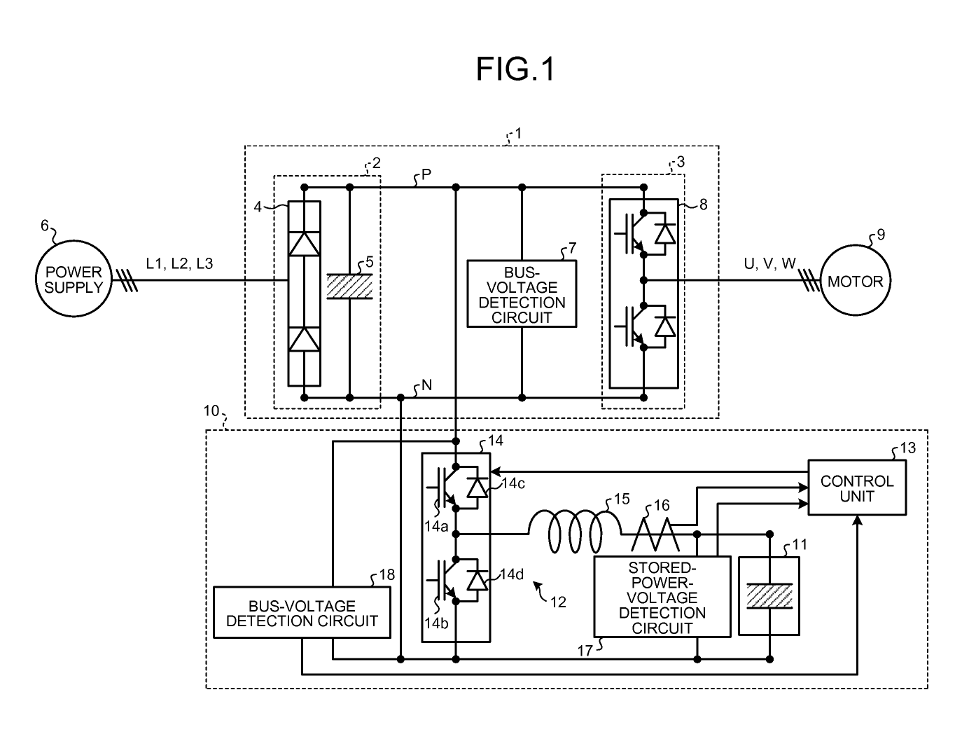

FIG. 1 is a block diagram for explaining the configuration of a power storage device that carries out a life diagnosis method for a power storage device according to an embodiment of the present invention and a connection relation between the power storage apparatus and a motor control apparatus. In FIG. 1, a motor control apparatus includes a converter circuit 2 and an inverter circuit 3 as basic components.

The converter circuit 2 is configured by a diode stack 4 and a main circuit capacitor 5. The diode stack 4 converts a three-phase (L1, L2, and L3) alternating-current power obtained from a three-phase alternating-current power supply 6 into direct-current power. A positive electrode bus P and a negative electrode bus N, which configure a direct-current bus, are connected to a positive electrode end and a negative electrode end of the converter 2. The main circuit capacitor 5 connected between the positive electrode bus P and the negative electrode bus N performs action for smoothing the direct-current voltage output to between the positive electrode bus P and the negative electrode bus N by the diode stack 4 and for generating and retaining the bus voltage.

It is seen from this circuit configuration that, right after power-on of the motor control apparatus 1, the converter circuit 2 does not immediately output a bus voltage of a predetermined value but outputs a bus voltage of a predetermined value required by the inverter 3 after a certain charging time (a period of initial charging) in the main circuit capacitor 5 or the like.

A bus-voltage detection circuit 7 detects the bus voltage output to the direct-current bus including the positive electrode bus P and the negative electrode bus N by the converter circuit 2 and outputs the bus voltage to a not-shown control circuit in the inverter circuit 3. In an inverter switching circuit 8 in the inverter circuit 3, a plurality of switching elements arranged between the positive electrode bus P and the negative electrode bus N, respectively connected to the positive electrode end and the negative electrode end of the converter 2 switch the bus voltage according to a driving signal from the control circuit in the inverter circuit 3, convert the bus voltage and generate a three-phase (U, V, and W) alternating-current voltage having arbitrary magnitude and frequency, and drive a motor 9 in an industrial machine (e.g., a numerical-control machine tool or a press machine).

A power storage apparatus 10 is connected to, in parallel to the inverter circuit 3, the positive electrode and the negative electrode end of the converter 2, that is, the positive electrode bus P and the negative electrode bus N included in the direct-current bus of the motor control apparatus 1. The power storage apparatus 10 includes a power storage device 11, a step-up/down chopper circuit 12, and a control unit 13.

The power storage device 11 includes a plurality of electric double layer capacitors and electrolytic capacitors connected in series and in parallel. A negative electrode end of the power storage device 11 is connected to the negative electrode bus N of the motor control apparatus 1. A positive electrode end of the power storage device 11 is connected to the positive electrode bus P of the motor control apparatus 1 via the step-up/down chopper circuit 12.

The step-up/down chopper circuit 12 includes a switching circuit 14 and a reactor 15. The switching circuit 14 includes a series circuit of two switching elements 14a and 14b. Diodes 14c and 14d are respectively connected in reverse parallel to the switching elements 14a and 14b. The collector terminal of the switching element 14a is connected to the positive electrode bus P of the motor control apparatus 1 together with the cathode terminal of the diode 14c. The emitter terminal of the switching element 14b is connected to the negative electrode bus N of the motor control apparatus 1 together with the anode terminal of the diode 14d. A connection end of the switching elements 14a and 14b and a connection end of the diodes 14c and 14d are connected to a positive electrode end of the power storage device 11 via the reactor 15.

A current sensor 16 detects the magnitude of an electric current flowing through the reactor 15 and outputs a detection value of the magnitude to the control unit 13. A stored-power-voltage detection circuit 17 detects a stored power voltage of the power storage device 11 and outputs a detection value of the stored power voltage to the control unit 13. A bus-voltage detection circuit 18 detects a bus voltage applied to both ends of the switching circuit 14 and outputs a detection value of the bus voltage to the control unit 13. Note that the bus-voltage detection circuit 18 can be omitted, and in that case, the control unit 13 can receive the bus voltage detected by the bus-voltage detection circuit 7 from the motor control apparatus 1.

The control unit 13 includes a function of controlling to turn on and off the switching elements 14a and 14b of the switching circuit 14 on the basis of the detection current value of the current sensor 16, the stored power voltage of the power storage device 11 detected by the stored-power-voltage detection circuit 17, and of the bus voltage, and causing the step-up/down chopper circuit 12 to perform a step-up operation (discharging control from the power storage device 11 to the direct-current bus) by the switching element 14b and the diode 14c and a step-down operation (charging control from the direct-current bus to the power storage device 11) by the switching element 14a and the diode 14d. Note that a signal for driving to turn on and off the switching elements 14a and 14b of the switching circuit 14 is a PWM signal. That is, discharging control and charging control performed during a normal operation is performed by current control of a variable frequency.

In this embodiment, a function of diagnosing the life of the power storage device 11 is added to the control unit 13 in addition to the two function explained above. The operations of units related to this embodiment are explained below with reference to FIG. 1 to FIG. 4.

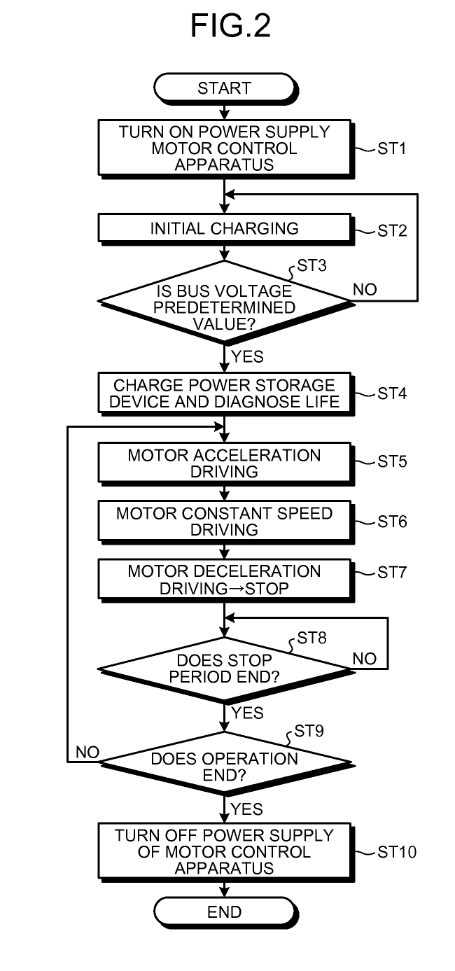

First, an operation sequence of the motor control apparatus 1 is explained according to FIG. 2 with reference to FIG. 1. Note that FIG. 2 is a flowchart for explaining the operation sequence of the motor control apparatus shown in FIG. 1.

In FIG. 2, when a power supply of the motor control apparatus 1 is turned on according to an operation start of a system to which the motor control apparatus 1 is applied (step ST1), charging (initial charging) for forming a predetermined bus voltage in the main circuit capacitor 5 is performed in the converter circuit 2 (step ST2). When the charging of the main circuit capacitor 5 advances, the bus-voltage detection circuit 7 detects that the bus voltage has reached a predetermined value required in the inverter circuit 3, and the bus-voltage detection circuit 18 detects that the bus voltage has been applied to both ends of the switching circuit 14 (Yes at step ST3). Then, the control voltage 13, which has received a notification from the bus-voltage detection circuit 18, drives the step-up/down chopper circuit 12 to perform charging to the power storage device 11 and, at the same time, performs life diagnosis of the power storage device 11 according to a method explained below (step ST4).

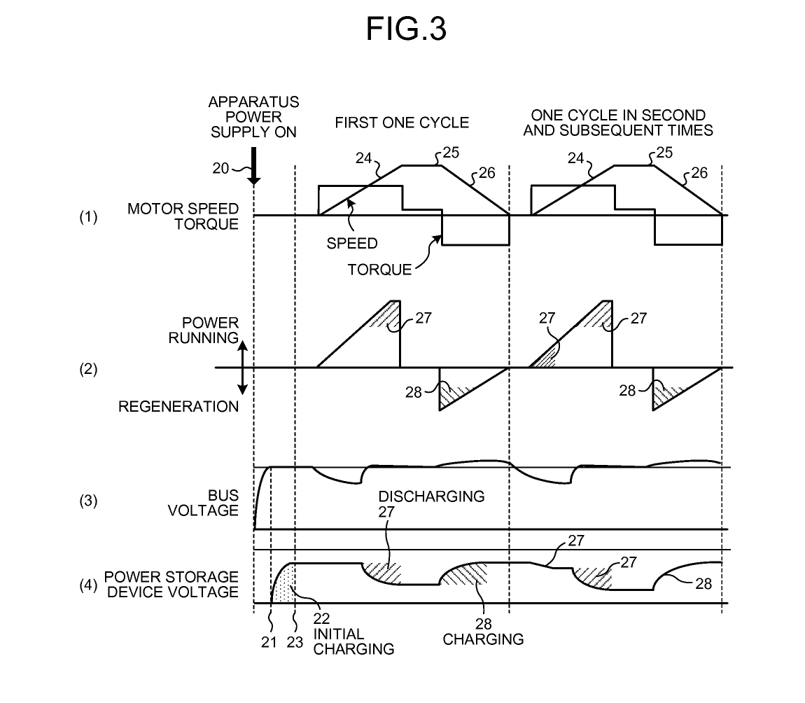

When the charging and the life diagnosis of the power storage device 11 (step ST4) finish, the control circuit in the inverter circuit 3 recognizes that the motor control apparatus 1 can be operated. Driving power is supplied from the inverter circuit 3 to the motor 9 and the motor 9 is driven (step ST5 to step ST7). Note that an operation period of step ST5 to step ST7 is a unit operation period of one cycle (see FIG. 3).

At step ST5, the motor 9 is driven to accelerate. During this acceleration driving, the motor 9 consumes large electric power. Therefore, direct-current power generated by the converter circuit 2 is sometimes insufficient for the acceleration driving. Therefore, during the power running in which the motor 9 is driven to accelerate, in order to cover the direct-current power output to the direct-current bus by the converter circuit 2, the control section 13 causes the switching element 14b to perform an ON/OFF operation in the step-up/down chopper circuit 12 to step up a charging voltage extracted from the power storage device 11 and supplies (discharges) the voltage to the direct-current bus, and compensates for the insufficient power during the power running.

In step ST6, the motor 9 is driven at constant speed. In this case, in the step-up/down chopper circuit 12, both the switching elements 14a and 14b are off. The inverter circuit 3 converts only the direct-current power generated by the converter circuit 2 and generates alternating-current power for driving the motor 9.

In step ST7, the motor 9 is driven to decelerate and stops at a predetermined position. During the deceleration driving, regenerative power output by the motor 9 functioning as a generator is output from the inverter circuit 3 to the direct-current bus. Therefore, during the regeneration in which the motor 9 is driven to decelerate, when the bus voltage rises with the regenerative power output from the inverter circuit 3 to the direct-current bus, the control unit 13 causes the switching element 14a to perform an ON/OFF operation in the step-up/down chopper circuit 12 to step down the bus voltage risen with the regenerative power, and captures the bus voltage into the power storage device 11 to store the power in (charge) the power storage device 11.

Some users operate the apparatus in an operation pattern starting from a regenerative operation. In the case of this use pattern, the initial charging of the power storage device 11 is unnecessary. It is possible to perform the life diagnosis in the same manner during the operation for charging regenerative energy.

In step ST8, the control circuit of the inverter circuit 3 determines whether or not the operation has ended and repeats the motor driving from step 5 to step 7 until the operation ends (No at step ST8). When the operation has come to an end (Yes at step ST8), the power supply of the motor control apparatus 1 is turned off (step ST10).

Note that the “operation end” means an end of a production activity in that day or an end of a scheduled production activity. Further, in the case of a continuous production without any rest, it means the timing at which apparatus power supply is turned off for its maintenance. In both the cases, when the apparatus power supply is turned on again, motor driving is performed through the processing period from step 2 to step 4. Taking notice of this point, this embodiment enables the life diagnosis of the power storage device to be surely performed without omission in the processing period from step 2 to step 4.

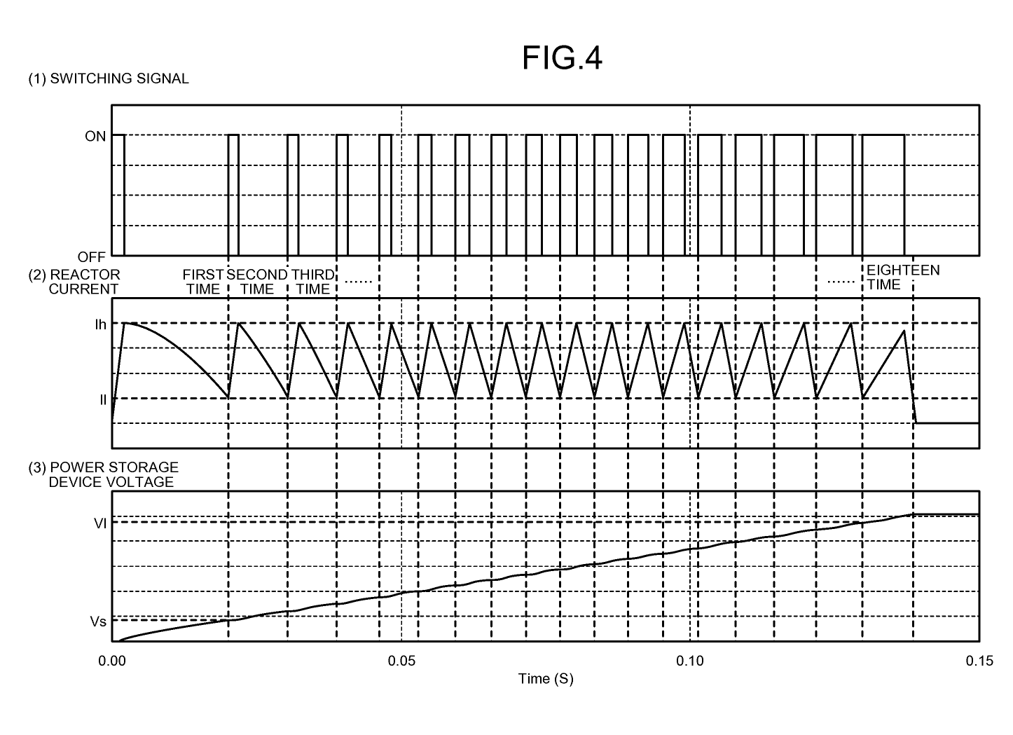

That is, in this embodiment, in the processing period of step 2 to step 4, after the bus voltage generated by the converter circuit 2 reaches the predetermined value required in the inverter circuit 3, the control unit 13 causes the switching element 14a in the step-up/down chopper circuit 12 to perform a predetermined number of ON/OFF operations to step down the bus voltage generated by the converter circuit 2, captures the bus voltage into the power storage device 11 to store the power in (charge) the power storage device 11 (see FIG. 3 and FIG. 4), and diagnoses the life of the power storage device 11 from an energy amount or the like consumed for the power storage in that process. The control circuit in the inverter circuit 3 recognizes that the motor control apparatus 1 has changed to the operable state after the completion of the charging to the power storage device 11 and performs the motor driving.

FIG. 3 is a time chart for explaining an operation example of power assist and charging performed by the power storage apparatus shown in FIG. 1. In FIG. 3, (1) a changing state of motor speed and torque, (2) discharging (power assist) during power running and charging during regeneration, (3) a changing state of the bus voltage, and (4) a changing state of a power storage device voltage in the steps from ST1 to ST7 in FIG. 2 are shown.

In FIG. 3, when the power supply of the motor control apparatus 1 is turned on at timing 20, the initial charging to the main circuit capacitor 5 is started in the converter circuit 2. At the timing 21, the charging voltage of the main circuit capacitor 5 reaches the predetermined bus voltage. In an example shown in the figure, the bus voltage at the timing 21 is the predetermined value required in the inverter circuit 3. The control circuit in the inverter circuit 3 recognizes that the motor control apparatus 1 is in the operable state when a notification of completion of the charging from the control unit 13 to the power storage device 11 is received.

When the charging voltage of the main circuit capacitor 5 reaches the predetermined bus voltage at the timing 21, the control unit 13 causes the chopper circuit 12 to step down the bus voltage and starts initial charging 22 for storing power in the power storage device 11. The initial charging 22 is completed at the timing 23 immediately after the elapse of a period determined by the number of ON/OFF operations of the switching element 14a from the timing 21. In FIG. 4, an example of operation content of the chopper circuit 12 for performing the initial charging 22 is shown. A combined period of “timing 20 to timing 21” and “timing 21 to timing 23” is an initial charging sequence.

When the control unit 13 detects the completion of the charging of the power storage device 11 at the timing 23, the control unit 13 notifies the control circuit in the inverter circuit 3 to that effect, stops the control of the chopper circuit 12, and estimates a deterioration degree of the power storage device 11 and diagnoses the life of the power storage device 11 according to a method explained below. If a method for displaying on a display is used as a method of notifying a diagnosis result, it is possible to perform appropriate notification corresponding to the deterioration degree.

After the elapse of a predetermining time from the timing 23 when the control circuit in the inverter circuit 3 receives the notification of the end of the initial charging 22 of the power storage device 11 from the control unit 13, the control circuit in the inverter circuit 3 starts the motor driving by the inverter switching circuit 8 in the inverter circuit 3. In FIG. 3(1), as a state of the motor driving, first one cycle and one cycle in the second and subsequent times are shown. Each of the one cycles of the motor driving includes an acceleration period 24, a constant speed period 25, and a deceleration period 26. As shown in FIG. 3(2) and (4), during the power running in which the motor is driven to accelerate, discharging (power assist) 27 is performed from the power storage apparatus 10 to the direct-current bus. During the regeneration in which the motor is driven to decelerate, charging 28 is performed from the direct-current bus to the power storage apparatus 10. As explained above, the discharging (the power assist) 27 and the charging 28 are performed by the current control of the variable frequency.

An operation for carrying out the life diagnosis of the power storage device 11 in the initial charging 22 shown in FIG. 3(4) is explained with reference to FIG. 4. Note that FIG. 4 is a time chart for explaining an example of a life diagnosis method for the power storage device carried out by the power storage apparatus shown in FIG. 1. In FIG. 4, (1) a switching signal given to the switching element 14a that causes to perform a step-down operation, (2) a reactor current detected by the current sensor 16, and (3) a change in a power storage voltage of the power storage device 11 are shown.

In the initial charging 22, an upper limit current Ih and a lower limit current Il of an electric current flowing to the reactor 15 are set in the control unit 13. The number of ON/OFF operations of the switching element 14a is set to, for example, eighteen. That is, the timing when the number of ON/OFF operations of the switching element 14a reaches eighteen is charging completion timing of the power storage device 11. Note that the number of ON/OFF operations of the switching element 14a changes depending on the setting of the upper limit current Ih and the lower limit current Il.

The switching signal given to the switching element 14a by the control unit 13 is a PWM signal as shown in FIG. 4(1). Therefore, the reactor signal detected by the current sensor 16 has a saw-tooth wave-like waveform as shown in FIG. 4(2). The switching element 14a is subjected to ON/OFF control to be kept to on until the reactor current detected by the current sensor 16 reaches the upper limit current Ih, to be turned off when the reactor current reaches the upper limit current Ih, to be kept to off until the reactor current reaches the lower limit current Il, and to be turned on when the reactor current reaches the lower limit current Il.

When the switching element 14a is on, energy is stored in the reactor 15 and the power storage device 11 with the energy from the direct-current bus. Charging of the power storage device 11 is carried out according to a difference between the bus voltage and the voltage of the power storage device 11. When the switching element 14a is off, the energy stored in the reactor 15 is charged in the power storage device 11. In FIG. 4(3), the voltage value Vs of the power storage device 11 is an initial value. In an example shown in FIG. 4, the voltage value Vl is a voltage obtained when the total amount of energy by eighteen times of the ON/OFF operation (the charging operation) is given to the power storage device 11.

The total amount of energy given to the power storage device 11 by eighteen times of the ON/OFF operation is calculated. The capacitance of the power storage device 11 can be calculated from the total amount of energy and the voltage value of the power storage device 11 at that time.

As a method of calculating the energy total amount, for example, energy EL of the reactor 15 during OFF of the switching element 14a is calculated from Formula (1). Note that, in Formula (1), L represents the inductance of the reactor 15.

EL=(½)*L*(Iĥ2−Il̂2) (1)

Energy EC stored in the power storage device 11 during ON of the switching element 14a is calculated from Formula (2). Note that, in Formula (2), Vpn represents a bus voltage value, Ton represents an ON time of the switching element 14a, and Toff represents an OFF time of the switching element 14a.

EC=(½)*(Ih+Il)*Vpn*Ton/(Ton+Toff) (2)

The energy EL and the energy EC are added up to calculate total energy EA given to the power storage device 11. Then, capacitance C of the storage device 11 can be calculated as Formula (3).

C=2*EA/(Vl̂2−Vŝ2) (3)

The control unit 13 compares the calculated capacitance C and initial capacitance of the power storage device 11 set in advance to thereby calculate a deterioration state as a ratio and diagnoses the life of the power storage device 11. When the deterioration state reaches a predetermined value, the control unit 13 shows warning display to a user of the system to which the motor control apparatus 1 is applied and urges the user to prepare the power storage device 11 for replacement. Consequently, the user can create a replacement preparation period for the power storage device 11, so that it is possible to minimize an apparatus stop time for performing replacement work.

As explained above, in the life diagnosis method for the power storage device according to this embodiment, during the initial charging for forming the predetermined bus voltage in the direct-current bus performed in the converter circuit at the time of the power-on of the system to which the motor control apparatus connected to the direct-current bus in parallel to the inverter circuit is applied, the power storage apparatus causes the step-down switching element in the step-up/down chopper circuit in the power storage apparatus to perform the ON/OFF operation the predetermined times according to the PWM signal, steps down the predetermined voltage formed in the direct-current bus by the converter circuit to apply the initial charging to the power storage device, calculates total energy given to the power storage device from the period in which the ON/OFF operations are performed the predetermined times and a current value flowing into the power storage device in the period, calculates actual capacitance of the power storage device from the calculated total energy and a charging voltage indicated by the power storage device, and estimates a deterioration degree of the power storage device and diagnoses the life of the power storage device on the basis of comparison of the calculated capacitance and the initial capacitance of the power storage device.

That is, according to this embodiment, it is possible to carry out the life diagnosis of the power storage device in the power storage apparatus using the existing circuits (the chopper circuit and the control unit) in the power storage apparatus. The step-down switching element of the chopper circuit is driven to be turned on and off by the PWM signal used during the normal operation. Therefore, the initial charging to the power storage device is performed by the current control of the variable frequency. Therefore, unlike the conventional technology, it is unnecessary to add a unit, a special circuit, a special mode, special adjustment, and an additional apparatus for charging at a fixed current and for life diagnosis.

Consequently, according to this embodiment, it is possible to add, without increasing costs, an additional function of life diagnosis of the power storage device to the power storage apparatus connected to the direct-current bus of the motor control apparatus and use it. Further, it is possible to display a deterioration degree of the power storage device, which is a diagnosis result, to the user. Therefore, the user can perform prior replacement preparation. It is possible to minimize an apparatus stop period for its replacement work.

Note that, in this embodiment, in the calculation of energy, energy during the initial charging and the last charging is not calculated. This is because a minimum current value during the initial charging and the last charging decreases to be lower than the lower limit current value Il and to be zero as shown in FIG. 4(2) and calculation becomes complicated. That is, when the user does not mind the calculation becomes complicated, the energy can be calculated.

In FIG. 4 showing this embodiment, the number of the charging operation is eighteen. However, the present invention is not limited to this number. When a small amount of charging such as several volts to several ten volts is applied to the power storage device 11, the charging can be completed and estimation of a life can also be completed by performing the charging operation once or twice. With these intentions, the number of the charging operation in the present invention is set to the predetermined number.

Further, as the calculation of energy, the current energy is calculated above. However, besides the electric energy, energy of charges given to the power storage device 11 can be calculated.

### INDUSTRIAL APPLICABILITY

As explained above, the life diagnosis method for the power storage device according to the present invention is useful as a life diagnosis method for a power storage device that can carry out life diagnosis of the power storage device in a power storage apparatus connected to a direct-current bus of a motor control apparatus using an existing circuit without requiring a special circuit and a special mode.

### REFERENCE SIGNS LIST

1 Motor driving control
2 Converter circuit
3 Inverter circuit
4 Diode stack
5 Main circuit capacitor
6 Three-phase alternating-current power supply
7 Bus-voltage detection circuit
8 Inverter switching circuit
9 Motor
10 Power storage apparatus
11 Power storage device
12 Step-up/down chopper circuit
13 Control unit
14 Switching circuit
14a, 14b Switching elements
14c, 14d Reflux diodes
15 Reactor
16 Current sensor
17 Stored-Power-voltage detection circuit
18 Bus-voltage detection circuit
20, 21, 23 Timings
22 Initial charging
24 Acceleration period
25 Constant speed period
26 Deceleration period
27 Charging
28 Discharging

1. A life diagnosis method for a power storage device included in a power storage apparatus connected to a direct-current bus in parallel to an inverter circuit in a motor control apparatus including a converter circuit that converts an alternating-current power supply into a direct-current power supply, and the inverter circuit that converts direct-current power output to the direct-current bus by the converter circuit and generates alternating-current power for controlling to drive a motor, the power storage apparatus including the power storage device, a step-up/down chopper circuit provided between the power storage device and the direct-current bus, and a control unit that performs discharging control for causing the step-up/down chopper circuit to perform a step-up operation and causing the power storage device to supply, to the direct-current bus, the direct-current power for supplementing the direct-current power output to the direct-current bus by the converter circuit and charging control for causing the step-up/down chopper circuit to perform a step-down operation and causing the power storage device to store regenerative power generated by the motor and output from the inverter circuit to the direct-current bus,
wherein the life diagnosis for the power storage device carried out by the control unit during initial charging for forming a predetermined bus voltage in the direct-current bus performed in the converter circuit when power is supplied to the motor control apparatus comprises:
a step of causing a step-down switching element to perform ON/OFF operations a predetermined times in the step-up/down chopper circuit to step down the predetermined bus voltage formed in the direct-current bus by the converter circuit, and applying the initial charging to the power storage device;
a step of calculating total energy given to the power storage device in a period in which the ON/OFF operations are performed the predetermined times;
a step of calculating actual capacitance of the power storage device from the calculated total energy and a charging voltage indicated by the power storage device; and
a step of estimating a deterioration degree of the power storage device and diagnosing the life of the power storage device on the basis of a comparison of the calculated actual capacitance and initial capacitance of the power storage device.
